(19) United States
(12) Patent Application Publication
(10) Pub. No.: US 2013/0270560 A1
(43) Pub. Date: Oct. 17, 2013

(54) METHOD FOR FORMING SEMICONDUCTOR DEVICE WITH EPITAXY SOURCE AND DRAIN REGIONS INDEPENDENT OF PATTERNING AND LOADING

(71) Applicants: Kangguo Cheng, Guilderland, NY (US); Ali Khakifirooz, Slingerlands, NY (US); Alexander Reznicek, Mount Kisco, NY (US); Yu Zhu, West Harrison, NY (US); Thomas N. Adam, Slingerlands, NY (US)

(72) Inventors: Kangguo Cheng, Guilderland, NY (US); Ali Khakifirooz, Slingerlands, NY (US); Alexander Reznicek, Mount Kisco, NY (US); Yu Zhu, West Harrison, NY (US); Thomas N. Adam, Slingerlands, NY (US)

(73) Assignee: INTERNATIONAL BUSINESS MACHINES CORPORATION, Armonk, NY (US)

(21) Appl. No.: 13/448,876

(22) Filed: Apr. 17, 2012

(51) Int. Cl. H01L 29/78; H01L 21/336

(52) U.S. Cl. 257/57; 438/157; 257/66; 257/E29.255; 257/E21.421

(57) ABSTRACT

A method of fabricating a semiconductor device that includes providing a gate structure on a channel portion of a semiconductor on insulator (SOI) layer of a semiconductor on insulator (SOI) substrate, and forming an amorphous semiconductor layer on at least a source region portion and a drain region portion of the SOI layer. The amorphous semiconductor layer is converted to a crystalline semiconductor material, wherein the crystalline semiconductor material provides a raised source region and a raised drain region of the semiconductor device. The method may be applicable to planar semiconductor devices and finFET semiconductor devices.

### BACKGROUND

The present disclosure relates generally to semiconductor devices. More particularly, the present disclosure relates to scaling of semiconductor devices.

In order to be able to make integrated circuits (ICs), such as memory, logic, and other devices, of higher integration density than currently feasible, one has to find ways to further downscale the dimensions of field effect transistors (FETs), such as metal-oxide-semiconductor field effect transistors (MOSFETs) and complementary metal oxide semiconductors (CMOS). Scaling achieves compactness and improves operating performance in devices by shrinking the overall dimensions and operating voltages of the device while maintaining the device's electrical properties.

### SUMMARY

A method of fabricating a semiconductor device is provided that, in one embodiment, includes providing a gate structure on a channel portion of a semiconductor substrate, and forming an amorphous semiconductor layer on at least a source region portion and a drain region portion of the semiconductor substrate. The amorphous semiconductor layer that is present on the source region and the drain region portions of the semiconductor substrate may then be converted into a crystalline semiconductor material. The crystalline semiconductor material provides a raised source region and a raised drain region of the semiconductor device.

In another aspect, a planar semiconductor device is provided that includes a gate structure on a channel portion of a semiconductor substrate and a raised source region and a raised drain region on the semiconductor substrate on opposing sides of the gate structure. Each of the raised source region and the raised drain region includes a single crystal semiconductor material that is in direct contact with the semiconductor substrate. The single crystal semiconductor material has a defect density that is less than 1×10⁵ defects/cm².

In yet another aspect, a method of forming a finFET semiconductor device is provided. In one embodiment, the method of fabricating the finFET semiconductor device includes providing a gate structure on a channel portion of a fin structure, and forming an amorphous semiconductor layer on at least the source region portion and the drain region portion of the fin structure. The amorphous semiconductor layer is formed on at least the opposing sides of the gate structure. The amorphous semiconductor layer that is present on the source region and drain region portions of the fin structure may then be converted to a crystalline semiconductor material. The crystalline semiconductor material provides a source region and a drain region of the finFET semiconductor device.

In yet another aspect of the present disclosure, a finFET semiconductor device is provided that includes a gate structure on a channel portion of a fin structure, and a source region and a drain region on the fin structure on opposing sides of the gate structure. Each of the source region and the drain region include a single crystal semiconductor material in direct contact with the fin structure. The single crystal semiconductor material has a defect density that is less than 1×10⁵ defects/cm².

### DESCRIPTION OF SEVERAL VIEWS OF THE DRAWINGS

The following detailed description, given by way of example and not intended to limit the present disclosure solely thereto, will best be appreciated in conjunction with the accompanying drawings, wherein like reference numerals denote like elements and parts, in which:

FIG. 1 is a side cross-sectional view depicting forming at least one gate structure on a semiconductor on insulator (SOI) substrate as used in one embodiment of a method of forming a planar semiconductor device in accordance with the present disclosure.

FIG. 2 is a side cross-sectional view depicting forming an amorphous semiconductor layer on at least a source region portion and a drain region portion of the semiconductor on insulator (SOI) layer of the SOI substrate, in accordance with one embodiment of the present disclosure.

FIG. 3 is a side cross-sectional view depicting converting the amorphous semiconductor layer that is present on the source region and drain region portions of the SOI layer into a crystalline semiconductor material, in accordance with one embodiment of the present disclosure.

FIG. 4 is a side cross-sectional view depicting one embodiment of removing a remaining portion of the amorphous semiconductor layer that is present over the gate structure, in accordance with the present disclosure.

FIG. 5 is a perspective view depicting one embodiment of forming a gate structure on at least one fin structure, as used in one embodiment of a method for forming a finFET semiconductor device, in accordance with the present disclosure.

FIG. 6A is a perspective view depicting one embodiment of forming an amorphous semiconductor layer on at least a source region portion and a drain region portion of the at least one fin structure, in accordance with one embodiment of the present disclosure.

FIG. 6B is a perspective view depicting another embodiment of forming an amorphous semiconductor layer, wherein the amorphous semiconductor layer fills the space between two adjacent fin structures.

FIG. 7A is a perspective view depicting converting the amorphous semiconductor layer depicted in FIG. 6A, which is present on the source region and drain region portions of the fin structures into a crystalline semiconductor material, in accordance with one embodiment of the present disclosure.

FIG. 7B is a perspective view depicting converting the amorphous semiconductor layer depicted in FIG. 6B into a crystalline semiconductor material, wherein the crystalline semiconductor material fills the space between two adjacent fin structures, in accordance with one embodiment of the present disclosure.

### DETAILED DESCRIPTION

Detailed embodiments of the methods and structures of the present disclosure are described herein; however, it is to be understood that the disclosed embodiments are merely illustrative of the disclosed methods and structures that may be embodied in various forms. In addition, each of the examples given in connection with the various embodiments of the disclosure are intended to be illustrative, and not restrictive. References in the specification to “one embodiment”, “an embodiment”, “an example embodiment”, etc., indicate that the embodiment described may include a particular feature, structure, or characteristic, but every embodiment may not necessarily include the particular feature, structure, or characteristic.

Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. For purposes of the description hereinafter, the terms “upper”, “lower”, “top”, “bottom”, and derivatives thereof shall relate to the disclosed structures, as they are oriented in the drawing figures. The terms “overlying”, or “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

Fully depleted semiconductor devices, such as fin field effect transistors (finFET) and planar semiconductor devices on extremely thin semiconductor on insulator (ETSOI) substrates, have been pursued as a device architecture for continued complementary metal oxide semiconductor (CMOS) scaling. Raised source regions and raised drain regions of epitaxial semiconductor material for planar devices on ETSOI substrates may reduce the source and drain resistance of the device. Further, epitaxially formed semiconductor material as the merged source and drain region for a finFET may also reduce source and drain resistance. It has however been determined that in some instances epitaxial growth processes may have a low throughput for manufacturing. Epitaxial growth and/or deposition is the growth of a semiconductor material on a deposition surface of a semiconductor material, in which the semiconductor material being grown from a gas precursor has the same crystalline characteristics as the semiconductor material of the deposition surface. Epitaxial growth may also have drawbacks, such as dependency on patterning and loading. For example, depending on the pitch, in planar semiconductor devices on ETSOI substrates including raised source and drain regions, the height of the raised source and drain region may vary from one pitch to another. In some embodiments, the methods and structures disclosed herein provide a high throughput method of forming raised source and drain regions for planar semiconductor devices on ETSOI substrates and merged source and drain regions in finFET semiconductor devices. In other embodiments, the methods and structures disclosed herein substitute epitaxial growth processes with a process sequence that includes depositing an amorphous semiconductor material, and then converting the deposited amorphous semiconductor layer to a crystal structure that is the same or similar to the crystal structure of the deposition surface on which the amorphous semiconductor material was deposited.

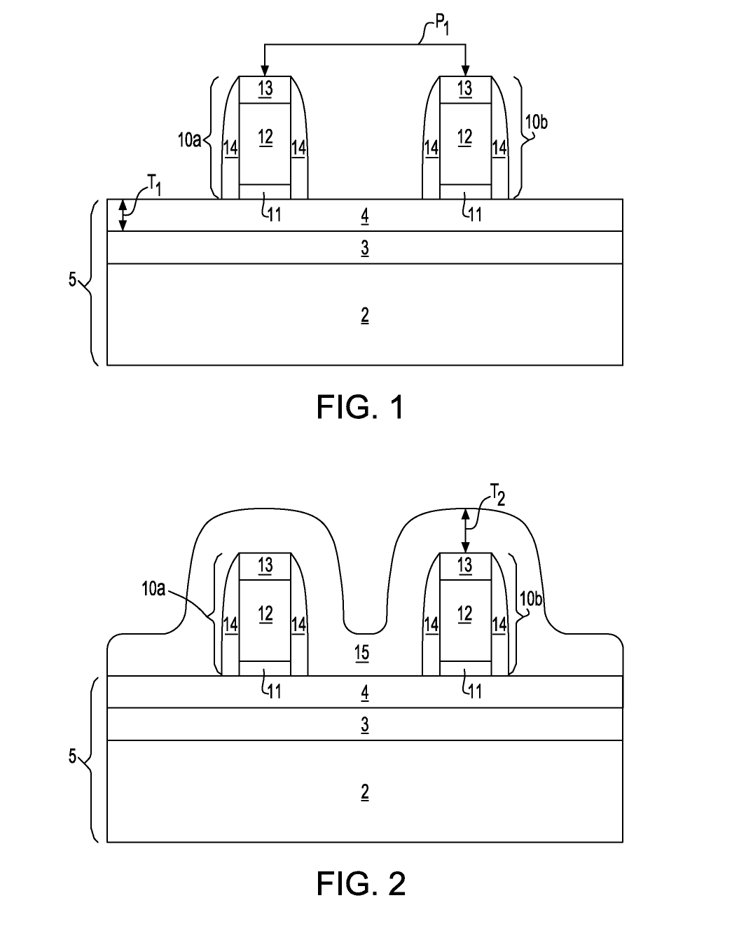

FIGS. 1-4B depict one embodiment of a method of forming a planar semiconductor device formed on an ETSOI substrate 5. As used herein, the term “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. The term “planar” as used to describe a semiconductor device denotes that the direction of charge carriers from the source region to the drain region of the semiconductor device is along a plane that is parallel to the upper surface of the substrate, wherein the gate structure is present on the upper surface of the substrate. In one embodiment, the planar semiconductor device is a field effect transistor (FET). Although, the semiconductor devices that are depicted in FIGS. 1-5 are FETs, the present disclosure is not limited to only this type of semiconductor device, as any semiconductor device having a planar orientation is suitable for use with the methods and structures of the present disclosure.

FIG. 1 illustrates the results of the processing steps that produce at least one gate structure 10a, 10b on an extremely thin semiconductor on insulator (ETSOI) substrate 5. The term “extremely thin semiconductor on insulator (ETSOI) substrate” denotes a semiconductor on insulator (SOI) substrate, in which the semiconductor on insulator (SOI) layer 4 (hereafter referred to as “extremely thin semiconductor on insulator (ETSOI) layer 4”) that is present on a buried dielectric layer 3 of the ETSOI substrate 5 has a thickness T₁ of 15 nm or less. The ETSOI substrate 5 may further include a base semiconductor layer 2. In some embodiments, the ETSOI layer 4 of the ETSOI substrate 5 has a thickness T₁ of 10 nm or less. Although the substrate that is depicted in the FIG. 1 is an ETSOI substrate 5, it is noted that the substrate may also be a bulk substrate or a semiconductor on insulator (SOI) substrate with a semiconductor on insulator (SOI) layer that is greater than 10 nm.

The semiconductor material that provides the ETSOI layer 4 may be any semiconducting material including, but not limited to (strained or unstrained) Si, Si:C, SiGe, SiGe:C, Si alloys, Ge, Ge alloys, any III-V, such as GaAs, InAs, and InP, or any combination thereof. In one embodiment, the semiconductor material that provides the ETSOI layer 4 is silicon (Si). The semiconductor material that provides the ETSOI layer 4 may be thinned to a desired thickness by planarization, grinding, wet etch, dry etch, oxidation followed by oxide etch, or any combination thereof. One method of thinning the semiconductor material for the ETSOI layer 4 is to oxidize the silicon by a thermal dry or wet oxidation process, and then wet etch the oxide layer using a hydrofluoric (HF) acid mixture. This process can be repeated to achieve the desired thickness. In one embodiment, the ETSOI layer 4 has a first thickness T1 ranging from 1.0 nm to 8.0 nm. In another embodiment, the ETSOI 4 has a first thickness T1 ranging from 2.0 nm to 6.0 nm. In one example, the ETSOI layer 4 has a first thickness T1 of 5.0 nm or 6.0 nm.

The ETSOI layer 4 is typically composed of a semiconductor material having a single crystal crystalline structure. The term “single crystal crystalline structure” denotes a crystalline solid, in which the crystal lattice of the entire sample is substantially continuous and substantially unbroken to the edges of the sample, with substantially no grain boundaries. For example, the ETSOI layer 4 may be composed of single crystal silicon (Si). The crystal orientation of the ETSOI layer 4 may be (100), (110) and (111). In one example, the ETSOI layer 4 may have a (100) crystal orientation.

[0024]The buried dielectric layer 3 that may be present underlying the ETSOI layer 4 and atop the base semiconductor layer 2 may be formed by implanting a high-energy dopant into a bulk semiconductor substrate and then annealing the structure to form a buried dielectric layer 3. In another embodiment, the buried dielectric layer 3 may be deposited or grown prior to the formation of the ETSOI layer 4. In yet another embodiment, the ETSOI substrate 5 may be formed using wafer-bonding techniques, where a bonded wafer pair is formed utilizing glue, adhesive polymer, or direct bonding.

The base semiconductor layer 2 may be a semiconducting material including, but not limited to Si, strained Si, SiC, SiGe, SiGeC, Si alloys, Ge, Ge alloys, GaAs, InAs, InP as well as other III/V and II/VI compound semiconductors. The base semiconductor layer 2 may have the same or a different composition than the ETSOI layer 4.

Still referring to FIG. 1, at least one gate structure 10a, 10b may be formed on a channel portion of the ETSOI layer 5. A “gate structure” is a structure used to control output current (i.e., flow of carriers in the channel) of a semiconducting device through electrical or magnetic fields. In one embodiment, each gate structure 10a, 10b includes at least one gate dielectric 11 and at least one gate electrode 12. The at least one gate structure 10a, 10b may be formed using deposition, photolithography and etch processes. For example, the material layers for the at least one gate dielectric 11 and the at least one gate electrode 12 may be deposited onto the ETSOI substrate 5 to provide a gate stack. Thereafter, the gate stack may be patterned and etched to provide the gate structures 10a, 10b. Specifically, and in one example, a pattern is produced by applying a photoresist to the surface to be etched, exposing the photoresist to a pattern of radiation, and then developing the pattern into the photoresist utilizing a resist developer. Once the patterning of the photoresist is completed, the sections of the sacrificial material covered by the photoresist are protected to provide the gate structures 10a, 10b, while the exposed regions are removed using a selective etching process that removes the unprotected regions. Following formation of the gate structures 10a, 10b the photoresist may be removed. Although FIG. 1 depicts only two gate structures 10a, 10b, the present disclosure is not intended to be limited to only this embodiment, as any number of gate structures 10a, 10b may be present on the ETSOI substrate 5. In some embodiments, the gate structures 10a, 10b may be separated by a pitch P1 ranging from 2500 nm to 2 nm. The pitch is the center to center distance separating adjacent gate structures 10a, 10b. In one embodiment, the gate structures 10a, 10b may be separated by a pitch P1 ranging from 3 nm to 90 nm.

The at least one gate dielectric 11 may be composed of any dielectric material including oxides, nitrides and oxynitrides. In one embodiment, the at least one gate dielectric 11 may be provided by a high-k dielectric material. The term “high-k” as used to describe the material of the at least one gate dielectric 11 denotes a dielectric material having a dielectric constant greater than silicon oxide (SiO₂) at room temperature (20° C. to 25° C.) and atmospheric pressure (1 atm). For example, a high-k dielectric material may have a dielectric constant greater than 4.0. In another example, the high-k gate dielectric material has a dielectric constant greater than 7.0. In an even further example, the dielectric constant of the high-k dielectric material may be greater than 10.0. In one embodiment, the at least one gate dielectric 11 is composed of a high-k oxide such as, for example, HfO₂, ZrO₂, Al₂O₃, TiO₂, La₂O₃, SrTiO₃, LaAlO₃, Y₂O₃ and mixtures thereof. Other examples of high-k dielectric materials for the at least one gate dielectric 11 include hafnium silicate, hafnium silicon oxynitride or combinations thereof. In one embodiment, the at least one gate dielectric 11 may be deposited by chemical vapor deposition (CVD). Variations of CVD processes suitable for depositing the at least one gate dielectric 11 include, but are not limited to, Atmospheric Pressure CVD (APCVD), Low Pressure CVD (LPCVD), Plasma Enhanced CVD (EPCVD), Metal-Organic CVD (MOCVD) and combinations thereof. In one embodiment, the thickness of the at least one gate dielectric 11 is greater than 0.8 nm. More typically, the at least one gate dielectric 11 has a thickness ranging from about 1.0 nm to about 6.0 nm.

In one embodiment, the at least one gate conductor 12 is composed of a metal or a doped semiconductor. Examples of metals that may be employed for the at least one gate conductor 12 may include, but are not limited to, W, Ni, Ti, Mo, Ta, Cu, Pt, Ag, Au, Ru, Ir, Rh, and Re, and alloys thereof. One example of a doped semiconductor that is suitable for the at least one gate conductor 12 is doped polysilicon, such as n-type doped polysilicon. The at least one gate conductor 12 may be formed by a deposition process, such as CVD, plasma-assisted CVD, plating, and/or sputtering, followed by planarization. The at least one gate conductor 12 may be a multi-layered structure. When a combination of conductive elements is employed, an optional diffusion barrier material, such as TaN or WN, may be formed between the conductive materials. In some embodiments, a dielectric gate cap 13 may be present on the upper surface of the at least one gate conductor 12. The dielectric gate cap 13 may be composed of any dielectric material, such as an oxide, nitride or oxynitride material. In one example, the dielectric gate cap 13 is composed of silicon nitride. The dielectric gate cap 13 is optional and may be omitted.

In some embodiments, at least one dielectric gate spacer 14 may be formed adjacent to the gate structures 10a, 10b, i.e., in direct contact with the sidewall of the gate structure 10a, 10b. In one embodiment, the at least one dielectric gate spacer 14 may be formed by using a blanket layer deposition, such as chemical vapor deposition, and an anisotropic etchback method. The at least one dielectric gate spacer 14 may have a width ranging from 2.0 nm to 15.0 nm, and may be composed of a dielectric, such as a nitride, oxide, oxynitride, or a combination thereof. The at least one dielectric gate spacer 14 is optional, and may be omitted.

In some embodiments, source extension regions and drain extension regions (not shown) may then be formed in the portions of the ETSOI layer 4 that are present on opposing sides of gate structure 10a, 10b, which may be referred to as the source and drain portions of the ETSOI layer 4. In one embodiment, the extension source region and the extension drain region are formed using in situ doping, an ion implantation process, plasma doping, gas phase diffusion, diffusion from a doped oxide or a combination thereof. The conductivity type of the extension source region and the extension drain region typically dictates the conductivity type of the semiconductor device. As used herein, “p-type” refers to the addition of impurities to an intrinsic semiconductor that creates deficiencies of valence electrons. In a silicon-containing ETSOI layer 4, examples of p-type dopants, i.e., impurities, include but are not limited to, boron, aluminum, gallium and indium. As used herein, “n-type” refers to the addition of impurities that contributes free electrons to an intrinsic semiconductor. In a silicon containing ETSOI layer 4 examples of n-type dopants, i.e., impurities, include but are not limited to antimony, arsenic and phosphorous.

FIG. 2 depicts forming an amorphous semiconductor layer 15 on at least a source region portion and a drain region portion of the ETSOI layer 4 what is on opposing sides of the at least one gate structure 10a, 10b. As used herein, the term “amorphous ” denotes a non-crystalline solid. The amorphous semiconductor layer 15 may be composed of any semiconductor material that may be deposited as a non-crystalline solid. Examples of semiconductor materials that are suitable for the amorphous semiconductor layer 15 include silicon (Si), silicon germanium (SiGe), germanium (Ge) and silicon doped with carbon (Si:C). Other examples of semiconductor materials that are suitable for the amorphous semiconductor layer 15 include compound semiconductors, such as III-V semiconductors, e.g., GaAs semiconductors. It is noted that the above list of semiconductors for the amorphous semiconductor layer 15 has been provided for illustrative purposes only and is not intended to limit the present disclosure, and any semiconductor that can be deposited as an amorphous material is suitable for use with the present disclosure.

Referring to FIG. 2, in one embodiment, the amorphous semiconductor layer 15 is deposited in direct contact with the source region portion and the drain region portion of the ETSOI layer 4 and is deposited over the gate structure 10a, 10b. The source region portion and the drain region portion of the ETSOI layer 4 that is in direct contact with the amorphous semiconductor layer 15 is typically composed of a single crystal semiconductor material. The amorphous semiconductor layer 15 may be a conformally deposited layer. The term “conformal” or “conformally deposited” denotes a layer having a thickness that does not deviate from greater than or less than 20% of an average value for the thickness of the layer. In one embodiment, the amorphous semiconductor layer 15 may be formed by a deposition step, such as chemical vapor deposition or physical vapor deposition. Examples of chemical vapor deposition suitable for depositing the amorphous semiconductor layer 15 include, but are not limited to, Atmospheric Pressure CVD (APCVD), Reduced Pressure CVD (RPCVD), Low Pressure CVD (LPCVD), Ultra-high Vacuum CVD (UHVCVD) and Plasma Enhanced CVD (PECVD), Metal-Organic CVD (MOCVD) and combinations thereof. In one embodiment, the amorphous semiconductor layer 15 may be formed by a chemical vapor deposition process in which the deposition temperature is in the range of 250° C. to 500° C. and the silane gas flow rate is in the range of about 0.5 slm to about 2 slm at pressures less than 200 torr.

In one embodiment, the amorphous semiconductor layer 15 is deposited by chemical vapor deposition, in which the deposition conditions are chosen to suppress the controlled desorption of hydrogen from the growth front. As an example, higher-order silanes (tri-silane, tetra-silane, penta-silane, etc.) have a much enhanced sticking coefficient and reactitvity with a semiconductor surface, as compared to silane. In combination with a low-temperature, but high-pressure deposition regime (as an example, but not limited to: 600 Torr and 400° C.), the rate of H-desorption is lower than the net deposition rate forcing a breakdown of ordered growth. The result is an amorphous phase, especially if gas-phase reactions (that also prevail at higher pressures) assist in pre-cracking the precursors. An addition of atomic crystal disruptors (such as carbon or dopants) also assists in early amorphous phases (i.e., at lower pressures and higher temperatures).

The thickness T₂ of the amorphous semiconductor layer 15 may range from 1000 nm to 1 nm. In another embodiment, the thickness T2 of the amorphous semiconductor layer 15 ranges from 2 nm to 50 nm.

The amorphous semiconductor layer 15 may be doped with an n-type or p-type dopant. In some embodiments, the amorphous semiconductor layer 15 may be in situ doped. By “in situ” it is meant that the dopant that dictates the conductivity type of the amorphous semiconductor layer 15 that provides the subsequently formed raised source and drain regions is introduced during the process step, e.g., deposition, that forms the amorphous semiconductor layer 15. The amorphous semiconductor layer 15 may also be doped to an n-type or p-type conductivity after it is deposited using an ion implantation process, plasma doping, gas phase diffusion, or a combination thereof. In a silicon-containing semiconductor material or other type IV semiconductor material (semiconductor material from type IV of the Periodic Table of Elements), examples of p-type dopants, i.e., impurities, include but are not limited to, boron, aluminum, gallium and indium. As used herein, “n-type” refers to the addition of impurities that contributes free electrons to an intrinsic semiconductor. In a silicon containing semiconductor material or other type IV semiconductor material, examples of n-type dopants, i.e., impurities, include but are not limited to antimony, arsenic and phosphorous.

The conductivity type of the dopant within the amorphous semiconductor layer 15 is consistent with the type of conductivity that is desired for the raised source and drain regions that are provided by the later formed crystalline semiconductor material that is converted from the amorphous semiconductor layer 15. In the embodiments in which source extension region and the drain extension region are formed in the source and drain portions of the ETSOI layer 4 before the amorphous semiconductor layer 15 is deposited, the amorphous semiconductor layer 15 is doped to have the same conductivity type as the extension source and drain regions. For example, when the extension source and drain regions are doped to an n-type conductivity, the amorphous semiconductor layer 15 is doped to an n-type conductivity. In some embodiments, in which the source and drain extension regions are not formed prior to depositing the amorphous semiconductor layer 15, source and drain extension regions may be formed by thermally diffusing the n-type or p-type dopant from the amorphous semiconductor layer 15 into the source and drain portions of the ETSOI layer 4.

FIG. 3 depicts one embodiment of converting the amorphous semiconductor layer that is present on the source region and drain region portions of the ETSOI layer 4 into a crystalline semiconductor material 20. Converting the amorphous semiconductor layer to the crystalline semiconductor material 20 may include increasing the temperature of amorphous semiconductor layer to a temperature ranging from 400° C. to 800° C., wherein the amorphous semiconductor layer that is in direct contact with the source and drain portions of the ETSOI layer 4 is converted to the crystalline semiconductor material 20. In some embodiments, the source and drain portions of the ETSOI layer 4 function as a seed layer that dictates the crystalline structure of the crystalline semiconductor material 20of the crystallized amorphous semiconductor layer. For example, if the ETSOI layer 4 is composed of a single crystal semiconductor material, the crystalline semiconductor material 20 is composed of a single crystal semiconductor material. For example, when the ETSOI layer 4 has a (100) orientation, the crystalline semiconductor material 20of the crystallized amorphous semiconductor layer will have a (100) orientation. Other crystalline orientations for the ETSOI layer 4 and the crystalline semiconductor material 20of the crystallized amorphous semiconductor layer include (110) and (111). When the ETSOI layer 4 is composed of a type III-V semiconductor, the III-V semiconductor material may have another crystal structure, like hexagonal for instance, wherein the crystal orientation may be (0001) or (1101). In these embodiments, the crystalline orientation of the crystalline semiconductor material 20 may be (0001) or (1101). Other crystalline orientations have also been contemplated, which are within the scope of the present disclosure.

In some embodiments, the crystalline semiconductor material 20 may include a single crystal portion that is in direct contact with the source and drain portions of the ETSOI layer 4, and a multicrystalline portion or polycrystalline portion that is separated from the ETSOI layer 4 by the single crystal portion of the crystalline semiconductor material 20. Contrary to a single crystal crystalline structure, a multicrystalline structure is a form of semiconductor material made up of randomly oriented crystallites and containing large-angle grain boundaries, twin boundaries or both. Multi-crystalline is widely referred to a polycrystalline material with large grains (of the order of millimeters to centimeters). Other terms used are large-grain polycrystalline, or large-grain multi-crystalline. The term polycrystalline typically refers to small grains (hundreds of nanometers, to hundreds of microns).

In one embodiment, the converting the amorphous semiconductor layer that is present in direct contact with the source and drain portions of the ETSOI layer 4 to the crystalline semiconductor material 20 includes increasing the temperature of the amorphous semiconductor layer using an annealing process, such as laser annealing or electron beam annealing. “Laser annealing” means increasing temperature by Light Amplification by Stimulated Emission of Radiation in which the wavelength ranges from about 248 nm to about 1064 nm, and the application of the pulse energy ranges from about 0.1 nanoseconds to about 100 nano seconds. In one embodiment, the intensity of the laser pulse may be between 1 to 100 MW/cm². “Electron beam annealing” refers to increasing temperature by irradiation of an electron beam, in which the accelerating potential of beam ranges from about 5 KeV to about 100 KeV, and the application the pulse energy ranges from 5 nanoseconds to about 100 nano seconds. Other forms of annealing that are suitable for converting the amorphous semiconductor layer to the crystalline semiconductor material 20 include furnace annealing or rapid thermal annealing (RTA).

In one embodiment, the amorphous semiconductor layer is converted to the crystalline semiconductor material 20 by increasing the temperature of the amorphous semiconductor layer that is in direct contact with the source and drain portions of the ETSOI layer 4 to greater than 400° C. and less than 800° C. In another embodiment, the amorphous semiconductor layer is converted to the crystalline semiconductor material 20 by increasing the temperature of the amorphous semiconductor layer that is in direct contact with the source and drain portions of the ETSOI layer 4 to greater than 600° C. and less than 700° C. In one example, to convert the amorphous semiconductor layer to the crystalline semiconductor material 20, the temperature of the amorphous semiconductor layer is increased to 650° C. Lower temperatures typically require longer annealing times. Long furnace anneals (several hours) are needed for crystallizing micrometers of amorphous silicon from a seed at temperatures below 600° C. Conversion of the amorphous semiconductor layer into the crystalline semiconductor material 20 may also be initiated by millisecond annealing at elevated temperatures, ion irradiation, metal catalization, or plasma enhancement techniques.

Still referring to FIG. 3, during the annealing process to form the crystalline semiconductor layer 20, the portion of the amorphous semiconductor layer (hereafter referred to as remaining amorphous semiconductor layer 15a) that is present over the at least one gate structure 10a, 10b is not converted into a crystalline material. In some embodiments, the remaining amorphous semiconductor layer 15a is not converted to a crystalline material, because it is not in contact with a semiconductor material during the annealing process that converts the portion of the amorphous semiconductor layer that is contact with the source and drain portions of the SOI layer 4 into the crystalline semiconductor layer 20. The remaining amorphous semiconductor layer 15a is in direct contact with a dielectric material of the dielectric gate cap 13 and the at least one dielectric gate spacer 14.

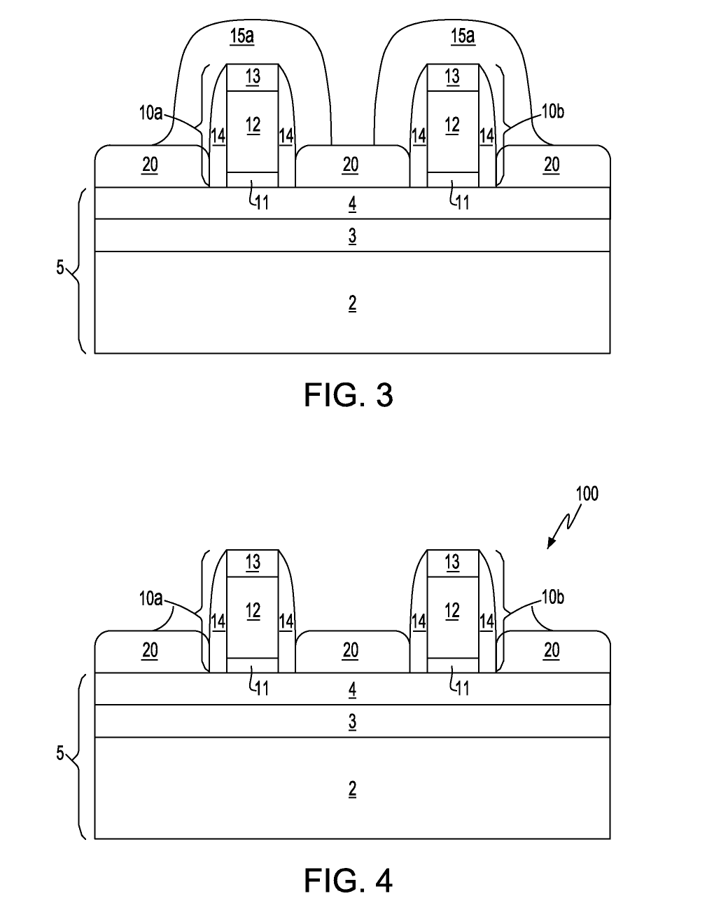

FIG. 4 depicts one embodiment of removing the remaining amorphous semiconductor layer 15a that is present over the gate structures 10a, 10b. In one embodiment, the remaining amorphous semiconductor layer 15a may be removed with a selective etch process. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 100:1 or greater. One example of an etch chemistry for removing the remaining amorphous semiconductor layer 15a selectively to the crystalline semiconductor material 20 is hydrochloric acid (HCl).

Referring to FIG. 4, the crystalline semiconductor material 20, provides the raised source and drain regions of the semiconductor device 100. As used herein, the term “source” is a doped region in the semiconductor device, in which majority carriers are flowing into the channel. As used herein, the term “drain” means a doped region in semiconductor device located at the end of the channel, in which carriers are flowing out of the transistor through the drain. The term “raised” as used to describe the raised source and drain regions means that the lower surface of the raised source and drain regions is in direct physical contact with the surface of the ETSOI substrate 5 on which the at least one gate dielectric 11 of the gate structures 10a, 10b is present. FIG. 4 depicts one embodiment of a planar semiconductor device 100 that includes gate structures 10a, 10b on a channel portion of a semiconductor substrate. e.g., ETSOI substrate 5. Raised source region and drain regions are present on the ETSOI substrate 5 on opposing sides of the gate structures 10a, 10b, wherein each of the raised source region and the raised drain region include a single crystal semiconductor material 20 in direct contact with the ETSOI substrate 5. In some embodiments, the single crystal semiconductor material 20 that provides the raised source and drain regions has a low defect density or is defect free. For example, the defect density of the single crystal semiconductor material may be less than 1×10⁵ defects/cm². In another example, the defect density of the single crystal semiconductor material may range from1×10² defects/cm² to 1×10⁵ defects/cm².

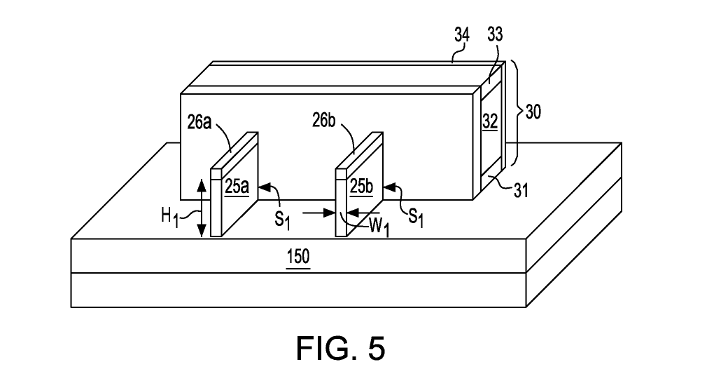

FIGS. 5-7 depict one embodiment of a method of fabricating a finFET semiconductor device. In one embodiment, the method may include providing at least one fin structure 25a, 25b having a width W1 of less than 20 nm. As used herein, the term “fin structure” refers to a semiconductor material, which is employed as the body of a semiconductor device, in which the gate structure is positioned around the fin structure such that charge flows down the channel on the two sidewalls of the fin structure and optionally along the top surface of the fin structure. In one embodiment, the fin structures 25a, 25b, and the dielectric layer 150 that the fin structures 25a, 25b are present on, may be provided from an SOI substrate, in which the SOI layer of the SOI substrate provides the fin structures 25a, 25b. One example of an SOI substrate suitable for forming the fin structures 25a, 25b that are depicted in FIG. 5 has been described above with reference to FIG. 1. The substrate depicted in FIG. 5 may further include a base semiconductor layer 2, which is similar to the base semiconductor layer 2 that is depicted in FIG. 1.

In one embodiment and prior to etching the SOI substrate to provide the fin structure 25a, 25b, a layer of the dielectric material can be deposited atop the SOI substrate to provide a dielectric fin cap 26a, 26b that is present on the upper surface of each fin structures 25a, 25b. The material layer that provides the dielectric fin caps 26a, 26b may be composed of a nitride, oxide, oxynitride material, and/or any other suitable dielectric layer. The material layer that provides the dielectric fin cap 26a, 26b can be formed by a deposition process, such as chemical vapor deposition (CVD) and/or atomic layer deposition (ALD). Alternatively, the material layer that provides the dielectric fin cap 26a, 26b may be formed using a growth process, such as thermal oxidation or thermal nitridation. The material layer that provides the dielectric fin cap 26a, 26b may have a thickness ranging from 1 nm to 100 nm.

In one embodiment and following the formation of the layer of dielectric material that provides the dielectric fin cap 26a, 26b, a photolithography and etch process sequence is applied to the material layer for the dielectric fin caps 26a, 26b and the SOI substrate to form each fin structures 25a, 25b. Specifically and in one example, a photoresist mask (not shown) is formed overlying the layer of the dielectric material that provides dielectric fin cap 26a, 26b and is present overlying the SOI layer of the SOI substrate, in which the portion of the dielectric material that is underlying the photoresist mask provides the dielectric fin caps 26a, 26b, and the portion of the SOI layer that is underlying the photoresist mask provides the fin structure 25a, 25b. The exposed portions of the dielectric material that provides dielectric fin cap 26a, 26b and the SOI layer, which are not protected by the photoresist mask, are removed using a selective etch process. In one embodiment, each of the fin structures 25a, 25b may have a height H₁ ranging from 5 nm to 200 nm. In another embodiment, each of the fin structures 25a, 25b has a height H₁ ranging from 10 nm to 100 nm. The fin structures 25a, 25b may each have a width W₁ of less than 20 nm. In one embodiment, the width W₁ of the fin structures 25a, 25b ranges from 2 nm to 20 nm. In one embodiment, each of the fin structures 25a, 25b has a width W₁ ranging from 3 nm to 8 nm. In another embodiment, the width W₁ of the fin structures 25a, 25b ranges from 2 nm to 4 nm. It is noted that any number of fin structures 25a, 25b may be formed.

FIG. 5 depicts one embodiment of forming a gate structure 30 on at least one fin structure 25a, 25b. Similar to the gate structures 10a, 10b depicted in FIG. 1, the gate structure 30 that is depicted in FIG. 5 can be formed utilizing deposition, photolithography and etch process steps. For example, a material layer for the gate structure 30 may be deposited over the fin structures 25a, 25b. Thereafter, a pattern corresponding to the geometry of the gate structures 30 is formed overlying the deposited material layer by applying a photoresist to the surface to be etched, exposing the photoresist to a pattern of radiation, and then developing the pattern into the photoresist utilizing a resist developer. Once the patterning of the photoresist is completed, the sections covered by the patterned photoresist are protected while the exposed regions are removed using a selective etching process that removes the unprotected regions. In one embodiment, the portion of the gate stack for the gate structure 30 that is removed exposes the sidewalls S1 of the fin structures 25a, 25b.

In one embodiment, the gate structure 30 includes at least one gate dielectric 31 that is present on, e.g., in direct contact with, the fin structures 25a, 25b, and at least one gate conductor 32 that is present on the at least one gate dielectric 31. The gate structure 30 may also include a gate dielectric cap 32 that is present on an upper surface of the at least one gate conductor 31. The at least one gate dielectric 31 is typically positioned on at least a portion of the sidewalls of the fin structures 25a, 25b, but may also be formed in direct contact with the dielectric fin caps 26a, 26b on the upper surface of the fin structures 25a, 25b. The gate structure 30 that is depicted in FIG. 5 is similar to the gate structures 10a, 10b that are described with reference to FIG. 1. Therefore, further details regarding the compositions for the at least one gate dielectric 31, and the at least one gate conductor 32 for the gate structure 30 depicted in FIG. 5 have been described above for the at least one gate dielectric 11 and the at least one gate conductor 12 that have been described above with reference to FIG. 1. In some embodiments, at least one spacer 34 may be formed in direct contact with the gate structure 30. The spacer 34 may be composed of a dielectric material, such as an oxide, nitride or oxynitride material. The spacers 34 may be formed using deposition and etch processes similar for forming the dielectric gate spacers 14 that are described above with reference to FIG. 1. The spacers 34 may have a width ranging from 1 nm to 10 nm, typically ranging from 1 nm to 5 nm. In some embodiments, extension source and the drain regions (not shown) may then be formed in the exposed portions of the fin structures 25a, 25b that are present on opposing sides of gate structure 30, which may be referred to as the source and drain portions of the fin structures 25a, 25b. In one embodiment, the extension source region and the extension drain region are formed using in situ doping, an ion implantation process, plasma doping, gas phase diffusion, diffusion from a doped oxide or a combination thereof. Further details regarding the formation of the extension source region and drain regions have been described above with reference to FIG. 1.

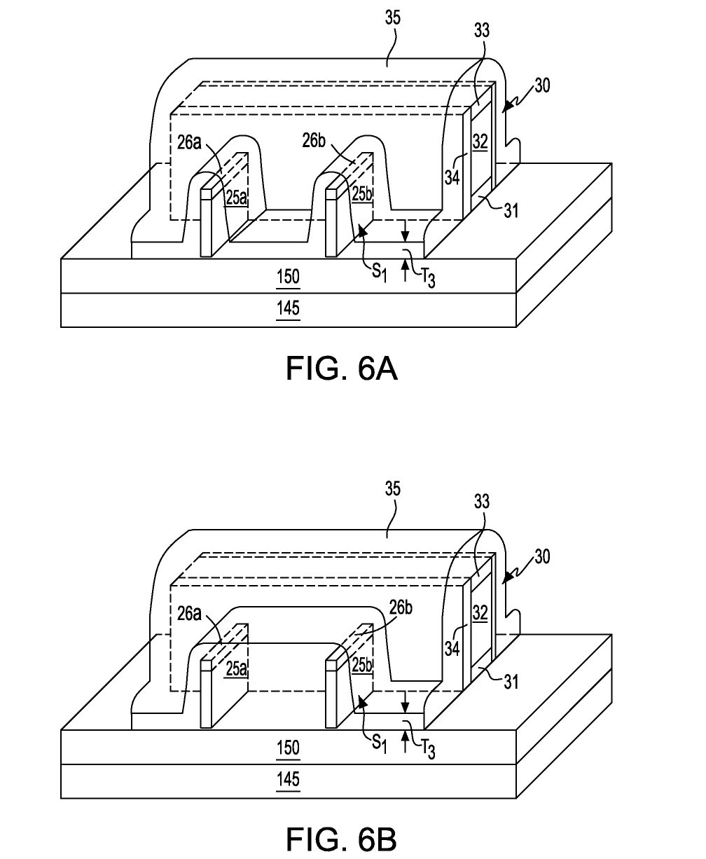

FIGS. 6A and 6B depict forming an amorphous semiconductor layer 35 on at least a source region portion and a drain region portion of the fin structures 25a, 25b on opposing sides of the at least one gate structure 30. The source region portion and the drain region portion of the fin structures 25a, 25b that is in direct contact with the amorphous semiconductor layer 35 is typically composed of a single crystal semiconductor material. The amorphous semiconductor layer 35 may be formed in direct contact with the exposed sidewalls Si of the fin structures 25a, 25b that includes the source region portion and the drain region portion of the fin structures 25a, 25b. The amorphous semiconductor layer 35 may be composed of any semiconductor material that may be deposited as a non-crystalline solid. Examples of semiconductor materials that are suitable for the amorphous semiconductor layer 35 include silicon (Si), silicon germanium (SiGe), germanium (Ge) and silicon doped with carbon (Si:C). Other examples of semiconductor materials that are suitable for the amorphous semiconductor layer 35 include compound semiconductors, such as III-V semiconductors, e.g., GaAs semiconductors. It is noted that the above list of semiconductors for the amorphous semiconductor layer 35 has been provided for illustrative purposes only and is not intended to limit the present disclosure, and any semiconductor that can be deposited as an amorphous material is suitable for use with the present disclosure.

The amorphous semiconductor layer 35 may be blanket deposited over the fin structures 25a, 25b and the gate structure 30. Referring to FIG. 6A, in some embodiments, the amorphous semiconductor layer 35 may be a conformally deposited layer. In one embodiment, the amorphous semiconductor layer 15 may be formed by a deposition step, such as chemical vapor deposition or physical vapor deposition. Referring to 6B, in some embodiments, the amorphous semiconductor layer 35 may be blanket deposited over the fin structures 25a, 25b and to fill the space between the adjacent fin structures 25a, 25b. The thickness T₃ of the amorphous semiconductor layer 35 may depend on the spacing between adjacent fin structures 25a, 25b, the width W1 of the fin structures 25a, 25b, and whether the amorphous semiconductor layer 35 is to be deposited as a conformal layers, as depicted in FIG. 6A, or if the amorphous semiconductor layer 35 is deposited to fill the space between the fin structures 25a, 25b. In one example, the thickness T₃ of the amorphous semiconductor layer 35 may range from 2 nm to 30 nm. In another example, the thickness T₃ of the amorphous semiconductor layer 35 ranges from 5 nm to 15 nm. The amorphous semiconductor layer 35 that is depicted in FIG. 6 is similar to the amorphous semiconductor layer 15 that is depicted in FIG. 2. Therefore, further details regarding the formation of the amorphous semiconductor layer 35 that is depicted in FIG. 6 can be found in the description of the amorphous semiconductor layer 15 that is depicted in FIG. 2.

The amorphous semiconductor layer 35 may be doped with an n-type or p-type dopant. In some embodiments, the amorphous semiconductor layer 15 may be in situ doped. The amorphous semiconductor layer 15 may also be doped to an n-type or p-type conductivity after it is deposited using an ion implantation process, plasma doping, gas phase diffusion, or a combination thereof. The conductivity type of the dopant within the amorphous semiconductor layer 35 typically provides of conductivity type of the finFET. More specifically, the conductivity type of the dopant in the amorphous semiconductor layer 35 typically provides the conductivity type in the source and drain regions, e.g., merged source and drain region, that are provided by the crystallized amorphous semiconductor layer 35, i.e., crystalline semiconductor material that is converted from the amorphous semiconductor layer 35. In some embodiments, in which the source and drain extension regions are not formed prior to depositing the amorphous semiconductor layer 35, source and drain extension regions may be formed in the fin structures 25a, 25b by thermally diffusing the n-type or p-type dopant from the amorphous semiconductor layer 35 into the source and drain portions of the fin structures 25a, 25b.

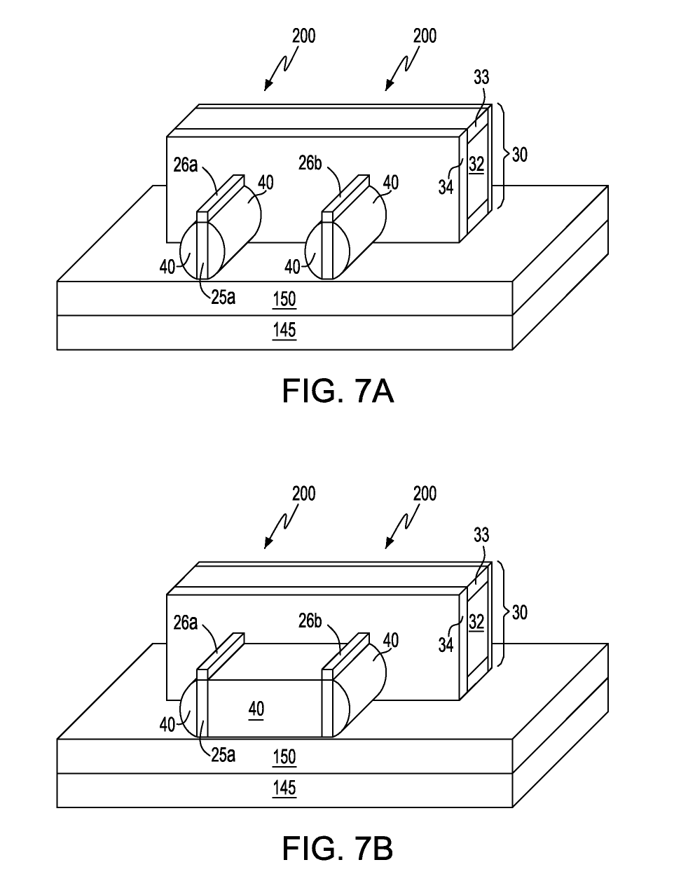

FIGS. 7A and 7B depict some embodiments of converting the amorphous semiconductor layer that is present on the source region and drain region portions of the fin structures 25a, 25b into a crystalline semiconductor material 40. FIG. 7A depicts converting the amorphous semiconductor layer that is depicted in FIG. 6A into a crystalline semiconductor material 40. In this embodiment, the crystalline semiconductor material 40 that is formed on the first fin structure 25a is separate from the crystalline semiconductor material 40 that is formed on the second fin structure 25b. (this sentence appears unclear to me) FIG. 7B depicts converting the amorphous semiconductor layer that is depicted in FIG. 6B into a crystalline semiconductor material 40. In FIG. 7B the crystalline semiconductor material 40 fills the space between two adjacent fin structures 25a, 25b. The crystalline semiconductor material 40 that fills the spacer between the two adjacent fin structures 25a, 25b may provide a merged source and drain region between and in contact with each of the adjacent fin structures 25a, 25b. By “merged source and drain region” it is meant that a single continuous semiconductor material, e.g., doped semiconductor material, is present between the two adjacent fin structures 25a, 25b, and is in direct contact with both of the adjacent fin structures 25a, 25b. Referring to FIGS. 7A and 7B, in one embodiment, the amorphous semiconductor layer is converted into a crystalline semiconductor material 40 having a single crystal crystalline structure. Converting the amorphous semiconductor layer to the crystalline semiconductor material 40 may include increasing the temperature of amorphous semiconductor layer to a temperature ranging from 400° C. to 800° C., wherein the amorphous semiconductor layer that is in direct contact with the source and drain portions of the fin structures 25a, 25b is converted to the crystalline semiconductor material 40. The source and drain portions of the fin structures 25a, 25b may as a seed layer that dictates the crystalline structure of the single crystal portion of the crystalline semiconductor material 40. Further, because the source and drain portions of the fin structures 25a, 25b function as a seed layer for the crystalline structure of the crystalline semiconductor material 40, the crystalline semiconductor material 40 will have the same crystalline orientation as the fin structures 25a, 25b.

In one embodiment, the converting the amorphous semiconductor layer that is present in direct contact with the source and drain portions of the fin structures 25a, 25b to the crystalline semiconductor material 40 includes increasing the temperature of the amorphous semiconductor layer using an annealing process, such as laser annealing or electron beam annealing. The crystalline semiconductor material 40 that is depicted in FIGS. 7A and 7B is similar to the crystalline semiconductor material 20 that is depicted in FIG. 3. Therefore, the method of converting the amorphous semiconductor layer into the crystalline semiconductor material 20 that is described above with reference to FIG. 3 is suitable for the method of converting the amorphous semiconductor layer into the crystalline semiconductor material 40 that is depicted in FIGS. 7A and 7B. In some embodiments, the crystalline semiconductor material 40 is composed of a single crystal semiconductor material. In some embodiments, the crystalline semiconductor material 40 includes a single crystal semiconductor material that is in direct contact with the sidewalls of the fin structures 25a, 25b, and a multicrystalline portion or polycrystalline portion that is separated from the sidewalls of the fin structures 25a, 25b by the single crystal semiconductor material.

Still referring to FIGS. 7A and 7B, during the annealing process to form the crystalline semiconductor material 40, the portion of the amorphous semiconductor layer that is present over the at least one gate structure 30 is not converted into a crystalline material. In one embodiment, the remaining amorphous semiconductor layer may be removed with a selective etch process. For example, the selective etch process may remove the remaining amorphous semiconductor layer selectively to the crystalline semiconductor material 40. In some embodiments, the etch process for removing the remaining amorphous semiconductor layer may also remove the polycrystalline portion (when present) of the crystalline semiconductor material 40. The etch process may also be selective to the gate dielectric cap 33, spacers 34 and the dielectric fin caps 26a, 26b. The crystalline semiconductor material 40 that remains on the sidewalls of the fin structures 25a, 25b provide the source and drain regions of the finFET semiconductor device 200.

FIGS. 7A and 7B depicts some embodiments of a finFET semiconductor device 200 that includes at least one gate structure 30 on a channel portion of at least one fin structure 25a, 25b, wherein source regions and drain regions on the at least one fin structure 25a, 25b are present on opposing sides of the at least one gate structure 30. Each of the source region and the drain region of the finFET 200 include a single crystal semiconductor material, i.e., crystalline semiconductor material 40, that is in direct contact with the at least one fin structure 25a, 25b. In some embodiments, the crystalline semiconductor material 40 that provides the source and drain regions is a single crystal semiconductor material that has a low defect density or is defect free. For example, the defect density of the single crystal semiconductor material of the crystalline semiconductor material 40 may be less than 1×10⁵ defects/cm². In another example, the defect density of the single crystal semiconductor material may range from 1×10² defects/cm² to 1×10⁵ defects/cm².

While the present disclosure has been particularly shown and described with respect to preferred embodiments thereof, it will be understood by those skilled in the art that the foregoing and other changes in forms and details may be made without departing from the spirit and scope of the methods and structures disclosed herein. It is therefore intended that the present disclosure not be limited to the exact forms and details described and illustrated, but fall within the scope of the appended claims.

1. A method of fabricating a semiconductor device comprising:
providing a gate structure on a channel portion of a semiconductor substrate;
forming an amorphous semiconductor layer on at least a source region portion and a drain region portion of the semiconductor substrate; and
laser annealing the amorphous semiconductor layer to convert the amorphous semiconductor layer that is present on the source region and drain region portions of the semiconductor layer to a crystalline semiconductor material, wherein the crystalline semiconductor material provides a raised source region and a raised drain region of the semiconductor device.

2. The method of claim 1, wherein the semiconductor substrate is a semiconductor on insulator (SOI) substrate, wherein the amorphous semiconductor layer is formed on at least the source region portion and the drain region portion of the semiconductor substrate, wherein the SOI layer of the SOI substrate has a thickness of less than 15 nm.

3. The method of claim 2, further comprising forming source and drain extension regions in the source region and drain region portions of the SOI layer prior to depositing the amorphous semiconductor layer.

4. The method of claim 3, wherein the source and drain extension regions are formed using ion implantation.

5. The method of claim 1, wherein the amorphous semiconductor layer is in situ doped with an n-type or p-type dopant.

6. The method of claim 1, wherein the amorphous semiconductor layer is deposited using a chemical vapor deposition process.

7. The method of claim 1, wherein the amorphous semiconductor layer is comprised of a silicon containing semiconductor selected from the group consisting of silicon, silicon germanium, silicon doped with carbon (Si:C) and combinations thereof.

8. (canceled)

9. The method of claim 1, wherein the forming of the amorphous semiconductor layer on said at least the source region portion and the drain region portion of the SOI layer further comprises forming the amorphous semiconductor layer on the gate structure, wherein following the converting of the amorphous semiconductor layer that is present on the source region and drain region portions of the SOI layer to the crystalline semiconductor material, a remaining portion of the amorphous semiconductor layer is present over the gate structure.

10. The method of claim 9, wherein the remaining portion of the amorphous semiconductor layer that is present over the gate structure is removed by an etch that is selective to the crystalline semiconductor material.

11-13. (canceled)

14. A method of fabricating a finFET semiconductor device comprising:
providing a gate structure on a channel portion of a fin structure;
forming an amorphous semiconductor layer on at least a source region portion and a drain region portion of the fin structure; and
laser annealing the amorphous semiconductor layer to convert the amorphous semiconductor layer that is present on the source region and drain region portions of the fin structure to a crystalline semiconductor material, wherein the crystalline semiconductor material provides a source region and a drain region of the finFET semiconductor device.

15. The method of claim 14, further comprising forming source and drain extension regions in the source region portion and the drain region portion of the fin structure prior to depositing the amorphous semiconductor layer.

16. The method of claim 14, wherein the amorphous semiconductor layer is comprised of a silicon containing semiconductor selected from the group consisting of silicon, silicon germanium, silicon doped with carbon (Si:C), and combinations thereof.

17. (canceled)

18-20. (canceled)

21. The method of claim 14, wherein the amorphous semiconductor layer is a III-V compound semiconductor.
